(19) United States
(12) Patent Application Publication
(10) Pub. No.: US 2013/0320004 A1
(43) Pub. Date: Dec. 5, 2013

(54) System and Method of Utilizing a Magnet For Attaching an Electrical Box to a Mounting Assembly

(71) Applicant: Jack Kerr, JR., Hearne, TX (US)

(72) Inventor: Jack Kerr, JR., Hearne, TX (US)

(21) Appl. No.: 13/888,426

(22) Filed: May 7, 2013

Related U.S. Application Data
(60) Provisional application No. 61/654,835, filed on Jun. 2, 2012.

(51) Int. Cl. H02G 3/10; H05K 13/00; H05K 5/00

(52) U.S. Cl. CPC H02G 3/105; H05K 5/0091; H05K 13/00
USPC 220/3.9; 29/468

(57) ABSTRACT

A system for attaching an electrical box to a mounting assembly. The system includes a metallic mounting assembly and a metallic electrical box. A permanent fastener is utilized for attaching the electrical box to the mounting assembly. A magnet is positioned on or near the electrical box and mounting assembly providing a magnetic attraction with the mounting assembly and the electrical box, thereby temporarily attaching the electrical box to the mounting assembly. In one embodiment, the magnet is a magnetic disc positioned in an indentation on a top surface of the electrical box. The fastener may be one or more screws attached to a mounting bracket affixed to the mounting assembly which is inserted through the top surface of the electrical box and into the interior of the electrical box.

### RELATED APPLICATIONS

This utility application claims the benefit of U.S. Provisional Patent Application Ser. No. 61/654,835 filed Jun. 2, 2012 by Jack R. Kerr which is hereby incorporated by reference.

### BACKGROUND OF THE INVENTION

1. Field of the Invention

This invention relates to support assemblies. Specifically, and not by way of limitation, the present invention relates to a system and method of utilizing a magnet for attaching an electrical box to a mounting assembly.

2. Description of the Related Art

In the construction of houses and buildings, it is quite common to have electrical boxes mounted to the wails or ceilings. These electrical boxes provide support and storage of various wiring devices, lighting fixtures, fans, and many other devices useful in a building. Electrical boxes also provide a space for electrical connections between the wiring device or fixture and the wiring of the building. These electrical boxes are normally attached to one or more structural supports, such as joists or studs. Often the electrical boxes include brackets for directly attaching the electrical box to the support member, while other electrical boxes are attached to a hanger or other support mounting assembly which extends between a pair of adjacent structural supports.

There are various mounting assemblies which are currently used for supporting ceiling fans or other fixtures between a pair of structural supports. These assemblies are usually attached to the ceiling joists by a brace, a bar hanger or other suitable member extending between the joist. FIG. 1 is a side view of an existing mounting assembly 10 and a separated electrical box 20. The mounting assembly includes an elongated member 12 having opposing end mounts 14 and 16. The end mounts 14 and 16 typically extend perpendicular to the elongated members. An electrical box 20 is normally attached to a bottom side 22 of the elongated members utilizing screws (not shown).

The elongated member is typically expanded to engage adjacent structural supports or joists (not shown). The elongated member is expanded until the end mounts 14 and 16 frictionally engage the structural supports or ceiling joists. Other mounting braces may also include sharp prongs or teeth which are driven into the joists by force.

Although the existing mounting assemblies are acceptable in many applications, the installation of the electrical boxes to the mounting assemblies can be extremely difficult and time-consuming. Frequently, the electric box must be attached to a mounting assembly in an area above the installers head. The installer must first locate and align the electrical box in its correct intended position. The installer must then maintain the correct position of the electrical box while attempting to fasten a screw into the electrical box.

Thus, the installation of these existing electrical boxes can be extremely difficult. Even experienced installers have tremendous difficulty when attempting to install the electrical box to the mounting assembly when the electrical box is located in awkward overhead locations,

Therefore, it would be advantageous to have a system and method of installing electrical boxes to mounting assemblies, even in awkward overhead locations, it is an object of the present invention to provide such a system and method.

### SUMMARY OF THE INVENTION

In one aspect, the present invention is a system for attaching an electrical box to a mounting assembly. The system includes a metallic mounting assembly and a metallic electrical box. A permanent fastener is utilized for attaching the electrical box to the mounting assembly, A magnet is positioned on or near the electrical box and mounting assembly providing a magnetic attraction with the mounting assembly and the electrical box, thereby temporarily attaching the electrical box to the mounting assembly. In one embodiment, the magnet is a magnetic disc positioned in an indentation on a top surface of the electrical box. The fastener may be one or more screws attached to a mounting bracket affixed to the mounting assembly which is inserted through the top surface of the electrical box and into the interior of the electrical box.

In another aspect, the present invention is a method of attaching an electrical box to a mounting assembly. The method begins by positioning a magnet on or near the electrical box and mounting assembly. A magnetic attraction is then created between the magnet and the electrical box and mounting assembly which enables the temporary attachment of the electrical box to the mounting assembly. Next, the electrical box is fastened to the mounting assembly with a fastener.

In another aspect, the present invention is directed to an electrical box attachable to a mounting assembly. The electrical box includes a main body having a top surface and a plurality of side walls surrounding an interior of the main body. The top surface includes an indentation. A magnet is positioned in the indentation. The electrical box is positioned against a mounting assembly, thereby providing a magnet attraction with the mounting assembly and temporality attaching the electrical box to the mounting assembly.

### BRIEF DESCRIPTION OF THE DRAWINGS

FIG. 1 (prior art) is a side view of an existing mounting assembly and a separated electrical box;

FIG. 2 is a top view of an electrical box in one embodiment of the present invention;

FIG. 3 is a top view of the magnetic disc inserted into the indentation in the electrical box of FIG. 2;

FIG. 4 (prior art) is a top view of the existing mounting assembly;

FIG. 5 is a side view of the electrical box prior to installation onto the mounting assembly;

FIG. 6 is a side view of the mounting screws being inserted through the screw openings of the electrical box;

FIG. 7 is a side view of the electrical box attached to the mounting assembly;

FIG. 8 is a bottom view of the electrical box attached to the mounting assembly;

FIG. 9 is an enlarged bottom view of the electrical box; and

FIG. 10 is a flow chart illustrating the steps of a method of installing the electrical box to the mounting assembly according to the teachings of the present invention.

### DESCRIPTION OF THE INVENTION

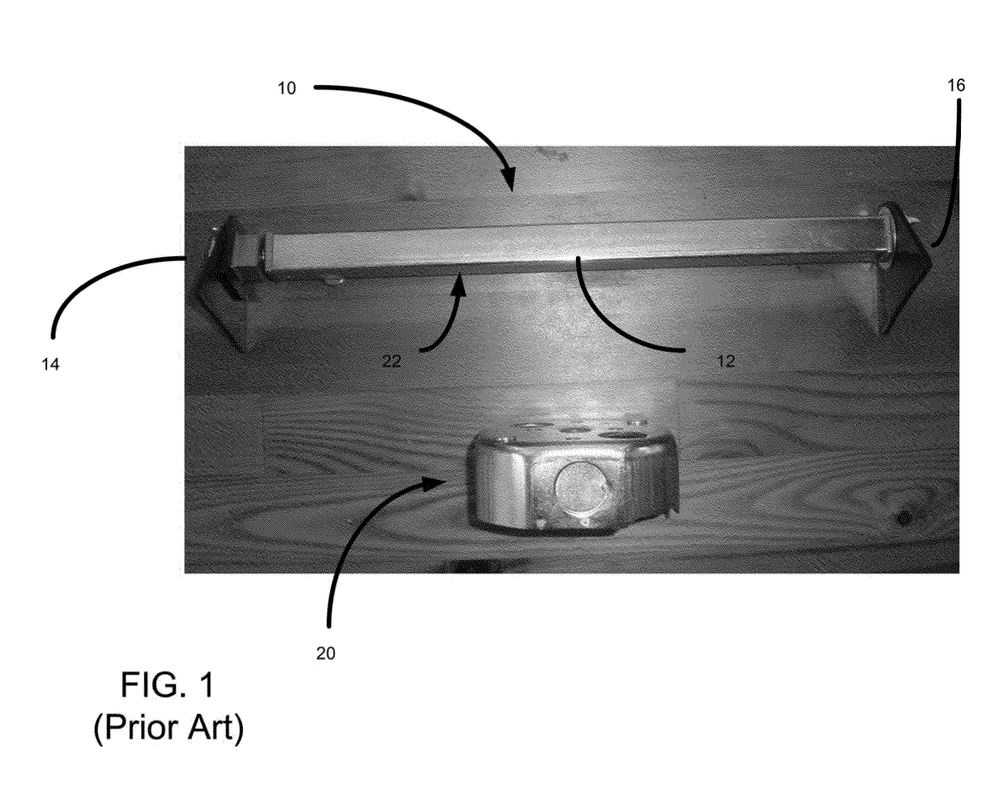

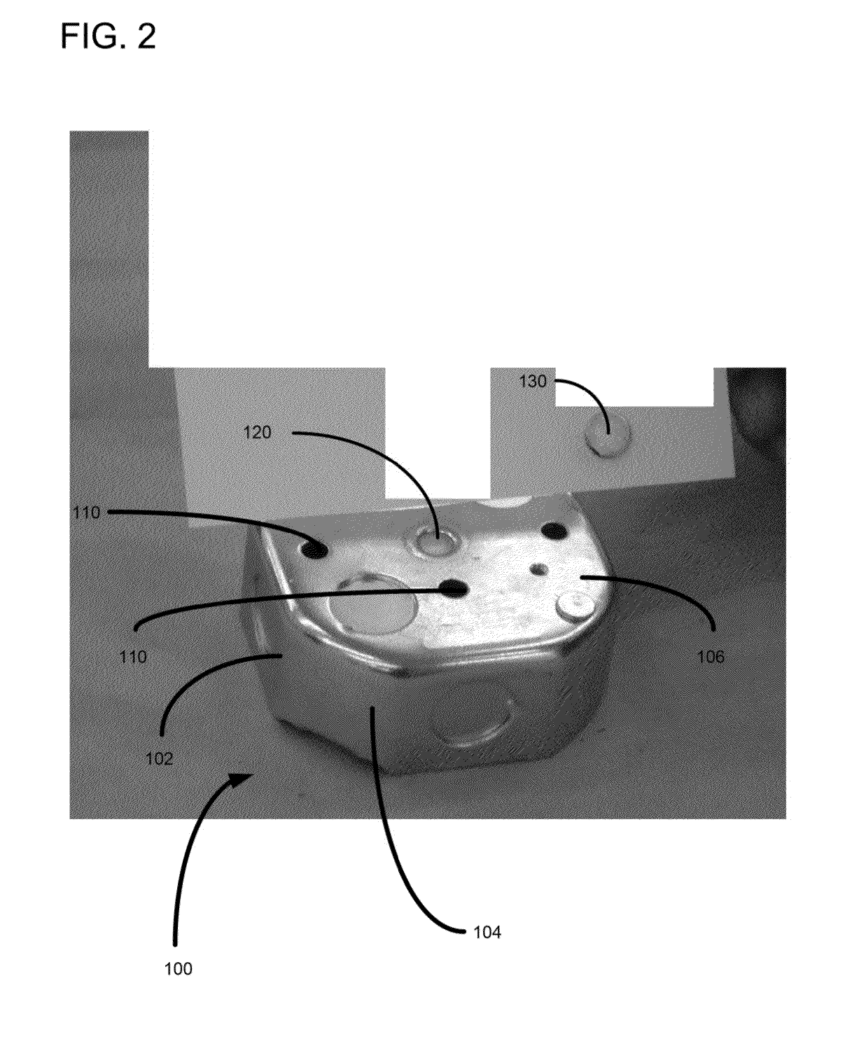

The present invention is a system and method of utilizing a magnet for installing an electrical box to a mounting assembly 10. FIG. 2 is a top view of an electrical box 100 in one embodiment of the present invention. The electrical box includes a main body 102 having side walls 104, a top surface 106 and an interior 108 (not shown in FIG. 1). The electrical box preferably includes a plurality of screw openings 110 sized and shaped for insertion of screws for installation to a mounting assembly. The electrical box may include an indentation 120 located on the top surface 106. FIG. 2 also illustrates a magnetic disc 130 sized and shaped to fit within the indentation 120 of the electrical box. The electrical box is preferably constructed of a metallic substance. In the preferred embodiment of the present invention, the magnet is of sufficient strength to retain the weight of the electrical box against a metallic surface during the installation process.

AG. 3 is a top view of the magnetic disc 130 inserted into the indentation 120 in the electrical box 100 of FIG, 2. In the preferred embodiment of the present invention, the magnetic disc is configured to lie flat within the indentation 120, thereby providing a flush or planar surface for the top surface 106.

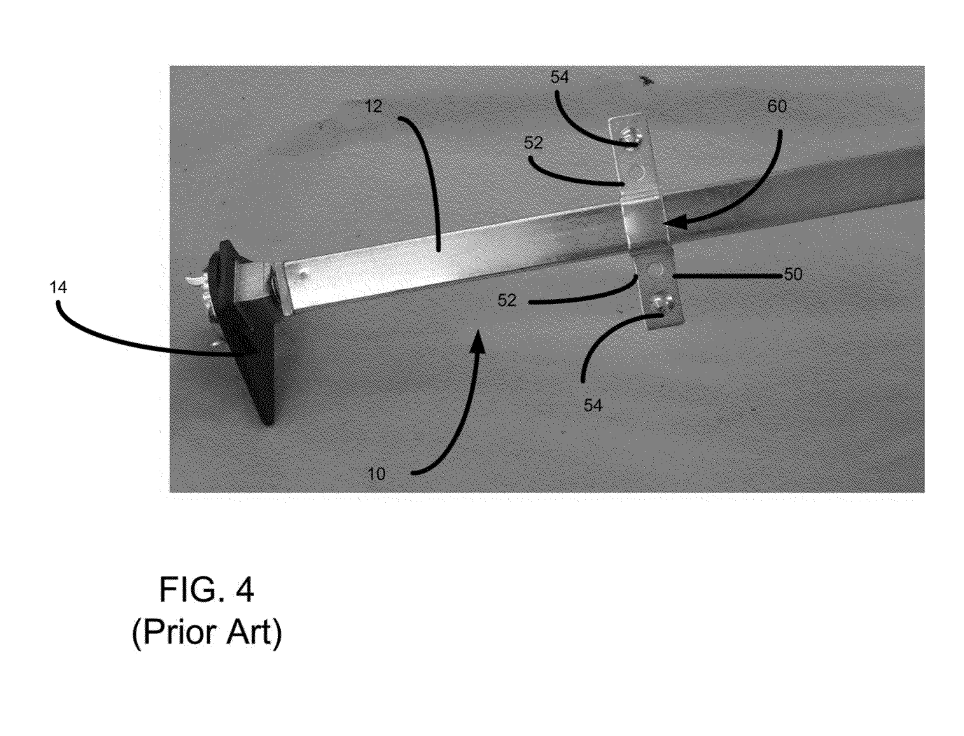

FIG. 4 is a top view of the mounting assembly 10. The mounting assembly typically includes the elongated member 12 having a square or rectangular cross section constructed of a metallic substance. As depicted in FIG. 4, the mounting assembly includes a mounting bracket 50 having extended arms 52. Each arm includes mounting screws 54 inserted through holes in the arms. The mounting bracket 50 includes a top portion 60 which is configured to fit snug in place over the top of the elongated member 12.

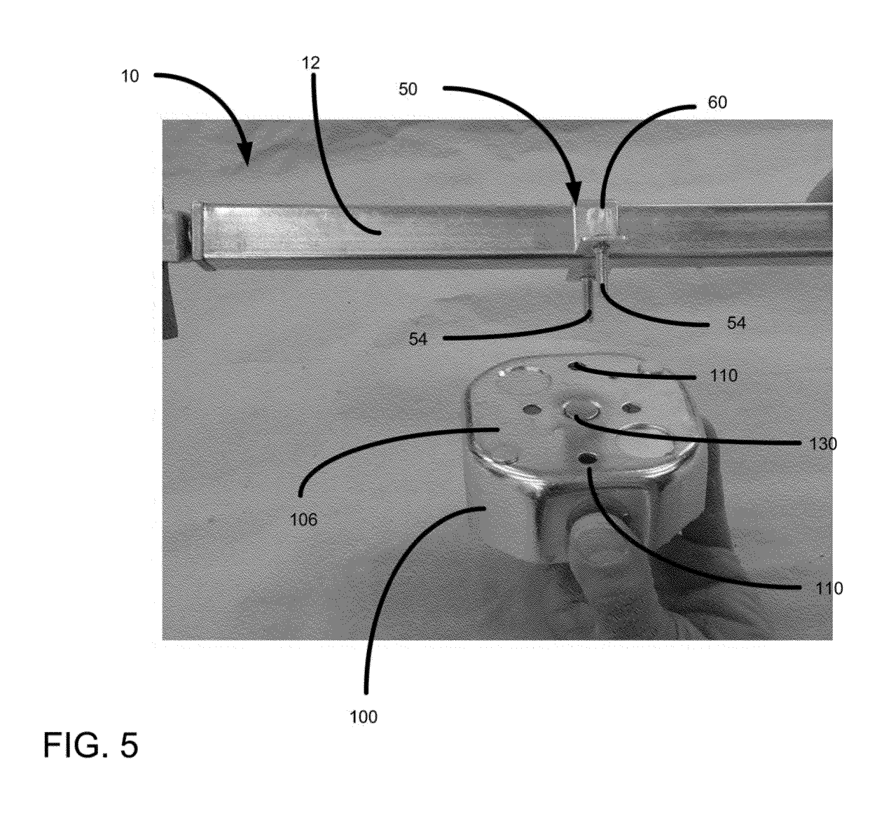

FIG. 5 is a side view of the electrical box 100 prior to installation onto the mounting assembly 10. The electrical box includes the magnetic disc 130 lying flush within the indentation 120 on the top surface 106. The electrical box is aligned to place the screw openings 110 with the mounting screws 54 of the mounting bracket 50.

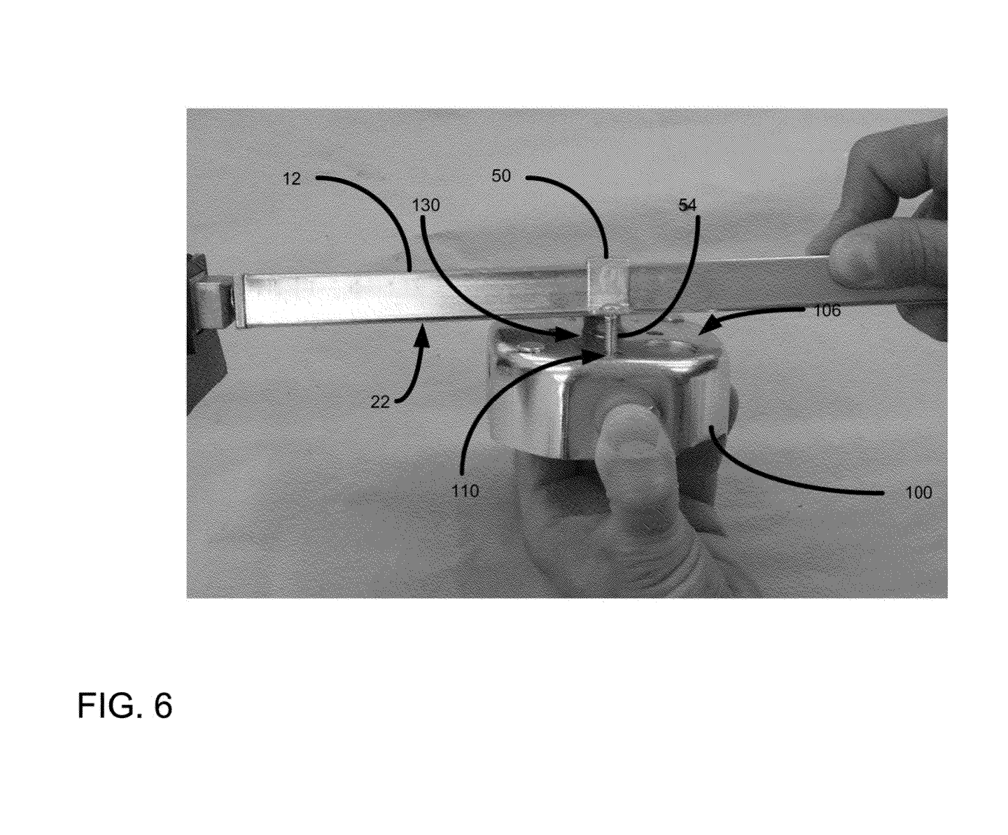

FIG. 6 is a side view of the mounting screws 154 being inserted through the screw openings 110 of the electrical box 100. The screws 154 are inserted through the openings 110 while allowing the bottom side 22 of the elongated member to contact the top surface 106 of the electrical box 100. The magnetic disc lies in between the electrical box and the bottom side 22 of the elongated member. The magnetic disc provides a magnetic attraction to the electrical box 100 and the elongated member 12, thereby temporarily attaching the electrical box 100 to the elongated member and mounting bracket 50.

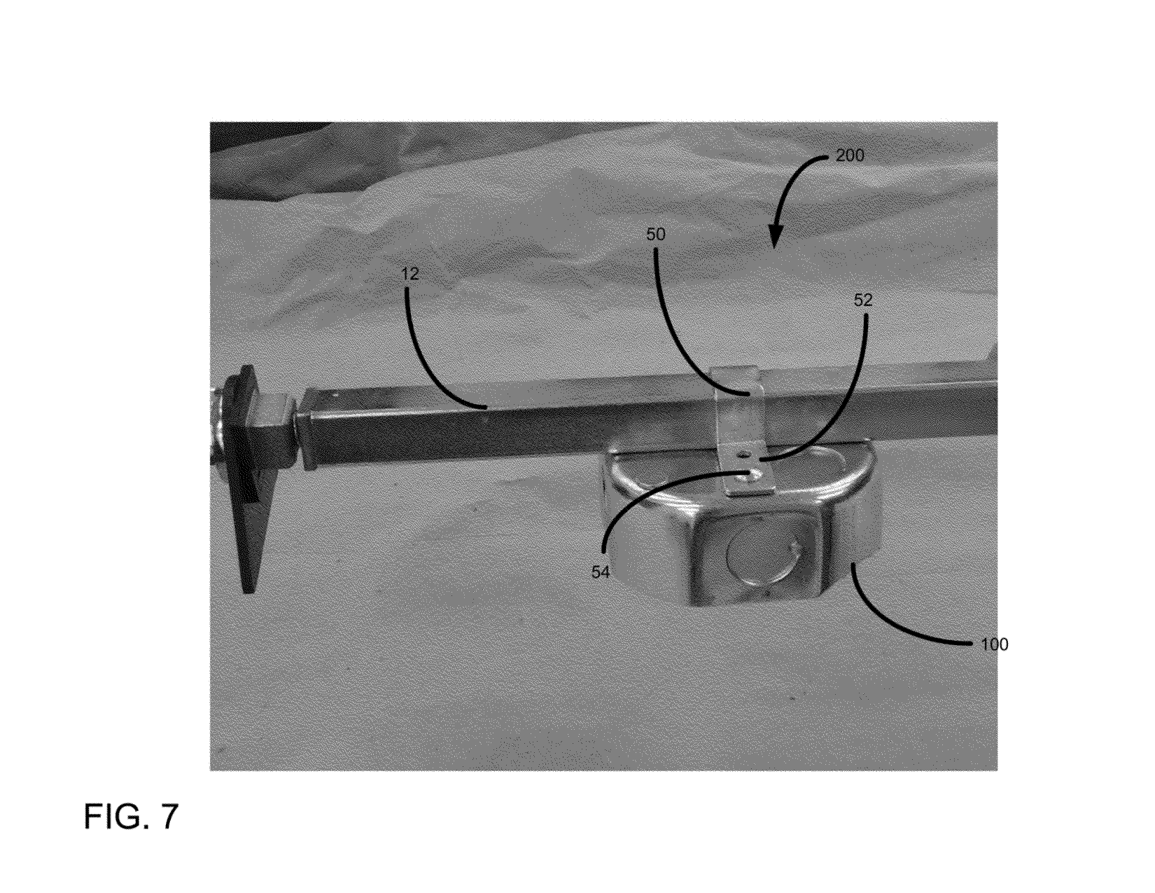

FIG. 7 is a side view of the electrical box 100 attached to the mounting assembly 10. The mounting screws 54 of the mounting bracket 50 are inserted through the screw openings 110 of the electrical box 100. In addition, the top surface 106 of the electrical box 100 contacts the bottom side 22 of the elongated member 12. The magnetic disc insures that the electrical box 100 is temporarily attached to the mounting assembly.

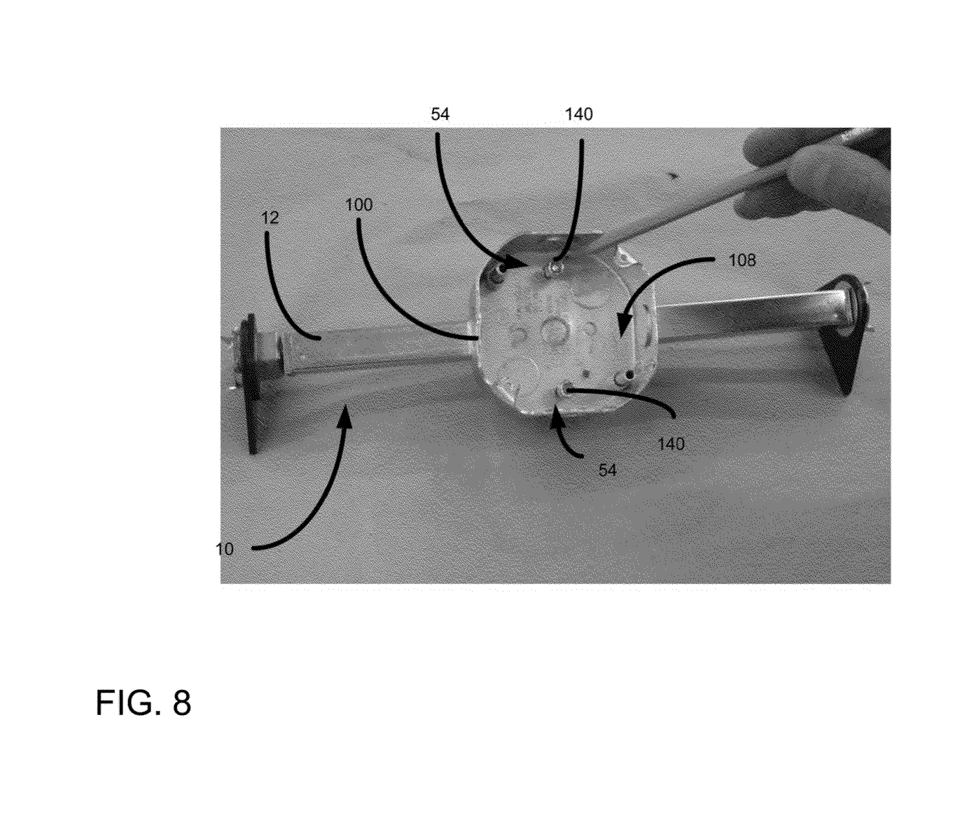

With the electrical box temporarily attached to the elongated member, an installer may more securely and permanently attach the electrical box 100 to the elongated member 12 of the mounting assembly 10. FIG. 8 is a bottom view of the electrical box 100 attached to the mounting assembly 10. FIG, 9 is an enlarged bottom view of the electrical box 100. As discussed above, the mounting screws are inserted through the screw openings 110 of the electrical box 100 and extend into the interior 108 of the electrical box 100. To more securely fasten the electrical box to the mounting assembly, screw nuts 140 may be attached to the mounting screws 54 and tightened to hold the electrical box 100 in place against the bottom side 22 of the elongated member 12.

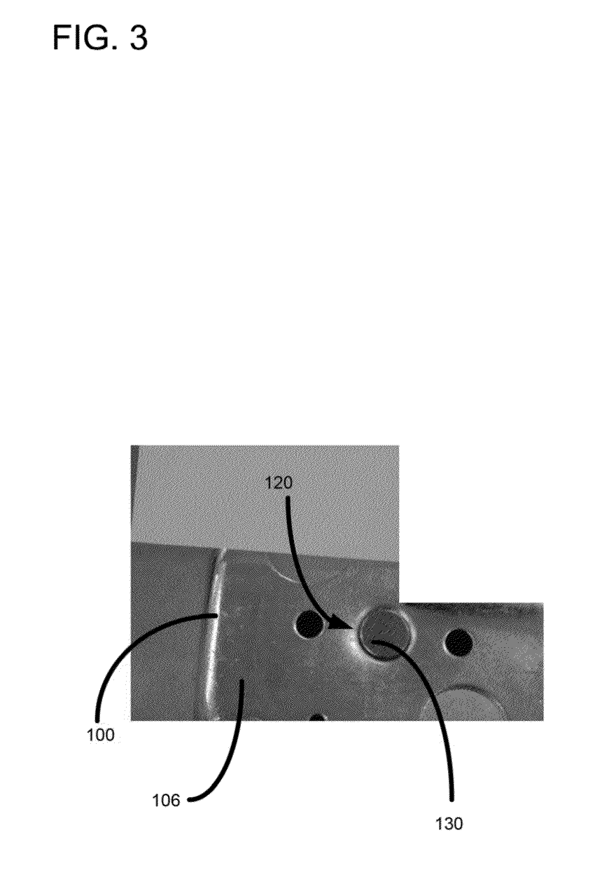

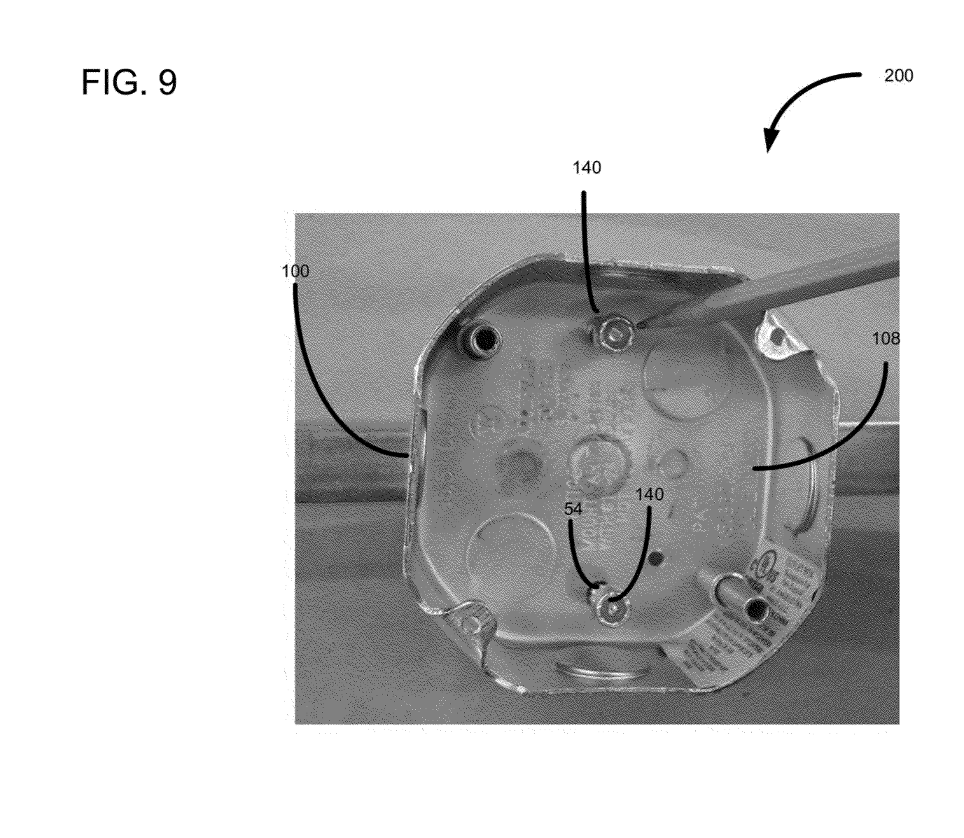

With reference to FIGS. 1-9, the operation of the system 200 will now be explained. First, the magnetic disc 130 is positioned within the indentation 108 of the electrical box 100. The electrical box is then aligned in such a fashion that the mounting screws 54 are inserted within the screw openings 110 of the electrical box. The magnetic disc provides a magnetic attraction which allows the electrical box 100 to be temporarily attached to the elongated member 12 of the mounting assembly 10. Typically, the mounting assembly is above the installers head, so this temporary attachment allows the installer to easily affix the electrical box 100 to the mounting assembly 10 without having to hold the electrical box in place. The installer then installs screw nuts 140 onto the mounting screws 54 of the mounting bracket 50. The installer may then tighten the screw nuts 140 as desired to securely fasten the electrical box to the mounting assembly.

The present invention may utilize any configuration of a magnet to provide an attraction between the electrical box and the mounting assembly. Although a magnetic disc is depicted, any magnet in any shape may be utilized and still remain in the scope of the present invention. Furthermore, the magnet may be located anywhere, either on the mounting assembly, on the electrical box or between the electrical box and the mounting assembly. In one embodiment, the magnet is located in the interior near an upper portion of the electrical box. The magnet may have sufficient magnet attraction to be attracted to the mounting assembly.

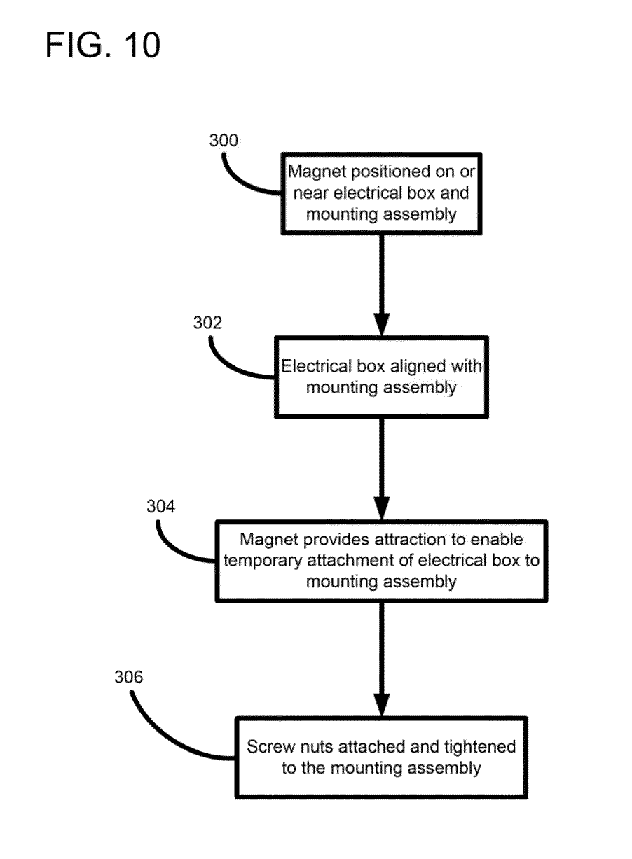

FIG. 10 is a flow chart illustrating the steps of a method of installing the electrical box 100 to the mounting assembly 10 according to the teachings of the present invention. With reference to FIGS. 1-10, the method will now be explained. The method begins with step 300 where the magnetic disc 130 is positioned within the indentation 108 of the electrical box 100. In other embodiments, any magnet may be utilized and positioned between the electrical box and the mounting assembly and still remain in the scope of the present invention. In an alternate embodiment, the magnet is place in the interior of the electrical box. Next, in step 302, the electrical box is then aligned in such a fashion that the mounting screws 54 are inserted within the screw openings 110 of the electrical box. In step 304, the magnetic disc provides a magnetic attraction which allows the electrical box 100 to be temporarily attached to the elongated member 12 of the mounting assembly 10. Typically, the mounting assembly is above the installer's head, so this temporary attachment allows the installer to easily affix the electrical box 100 to the mounting assembly 10 without having to hold the electrical box in place with the installer's hand. The method then moves to step 306 where the installer then installs screw nuts 140 onto the mounting screws 54 of the mounting bracket 50. The installer may then tighten the screw nuts 140 as desired to securely fasten the electrical box to the mounting assembly. In other embodiments, the installer may use any fastening device to more securely attach the electrical box to the mounting assembly.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

Thus, the present invention has been described herein with reference to a particular embodiment for a particular application. Those having ordinary skill in the art and access to the present teachings will recognize additional modifications, applications and embodiments within the scope thereof.

It is therefore intended by the appended claims to cover any and all such applications, modifications and embodiments within the scope of the present invention.

What is claimed is:

1. A system for attaching an electrical box to a mounting assembly, the system comprising:
a metallic mounting assembly;
a metallic electrical box;
a permanent fastener for attaching the electrical box to the mounting assembly;
a magnet positioned on or near the electrical box and mounting assembly providing a magnetic attraction with the mounting assembly and the electrical box thereby temporarily attaching the electrical box to the mounting assembly.

2. The system according to claim 1 wherein the magnet positioned between the mounting assembly and the electrical box.

3. The system according to claim 2 wherein the magnet is a magnetic disc positioned in an indentation on a top surface of the electrical box.

4. The system according to claim 1 wherein the magnet is positioned on the mounting assembly.

5. The system according to claim 1 wherein the permanent fastener includes a screw attached to a mounting bracket affixed to the mounting assembly, the screw being positioned through a top surface of the electrical box into an interior of the electrical box.

6. A method of attaching an electrical box to a mounting assembly, the method comprising the steps of.
positioning a magnet on or near the electrical box and mounting assembly;
providing a magnetic attraction between the magnet and the electrical box and mounting assembly thereby temporarily attaching the electrical box to the mounting assembly;
fastening the electrical box to the mounting assembly with a fastener.

7. The method according to claim 6 wherein the step of positioning a magnet includes positioning the magnet between a top surface of the electrical box and a bottom side of the mounting assembly;

8. The method according to claim 7 wherein the magnet is a magnetic disc positioned in an indentation on a top surface of the electrical box.

9. The method according to claim 6 wherein the step of positioning a magnet includes positioning the magnet on the mounting assembly.

10. The method according to claim 6 wherein the permanent fastener includes a screw attached to a mounting bracket affixed to the mounting assembly, the screw being positioned through a top surface of the electrical box into an interior of the electrical box.

11. An electrical box attachable to a mounting assembly, the electrical box comprising:
a main body having a top surface and a plurality of side walls surrounding an interior:
wherein the top surface includes an indentation; and
a magnet positioned in the indentation;
whereby the electrical box is positioned against a mounting assembly, thereby providing a magnet attraction with the mounting assembly and temporality attaching the electrical box to the mounting assembly.

12. The electrical box according to claim 11 wherein the magnet is a magnetic disc.
